(19) United States
(12) Patent Application Publication
(10) Pub. No.: US 2026/0184979 A1
(43) Pub. Date: Jul. 2, 2026

(54) RESIN COMPOSITION FOR MOLDING MEMBER AND SEMICONDUCTOR PACKAGE USING RESIN COMPOSITION

(71) Applicant: Samsung Electronics Co., Ltd., Suwon-si (KR)

(72) Inventor: Taehyung Lee, Suwon-si (KR)

(21) Appl. No.: 19/429,840

(22) Filed: Dec. 22, 2025

(30) Foreign Application Priority Data
Dec. 27, 2024 (KR) 10-2024-0199344

(51) Int. Cl. C09K 5/06; C08K 9/10; C08L 63/00; H10W 74/47

(52) U.S. Cl. CPC C09K 5/063; C08K 9/10; C08L 63/00; H10W 74/473; C08K 2201/001; C08K 2201/005; C08L 2203/20; C08L 2205/20

(57) ABSTRACT

A resin composition for forming a molding member included in a semiconductor package includes about 2 wt % to about 10 wt % of epoxy resin, about 2 wt % to about 10 wt % of a hardener, about 50 wt % to about 90 wt % of a filler, about 5 wt % to about 20 wt % of a phase-change material composite particle, and about 0 wt % to about 5 wt % of an additive, and the phase-change material composite particle includes a core particle including a phase-change material and a shell layer surrounding a surface of the core particle and including an organic material or an inorganic material. A semiconductor package includes a molding member that is manufactured using the resin composition.

### CROSS-REFERENCE TO RELATED APPLICATION

This application claims priority under 35 U.S.C. § 119 to Korean Patent Application No. 10-2024-0199344, filed on Dec. 27, 2024, in the Korean Intellectual Property Office, the disclosure of which is incorporated by reference herein in its entirety.

### BACKGROUND

With the rapid development of the electronics industry and users' needs, electronic devices have become compact and light. Accordingly, high integration density of semiconductor devices that are core parts of electronic devices are desired. In semiconductor packages, molding members protect semiconductor chips from external environments and physical/mechanical elements. In semiconductor packages including highly integrated semiconductor chips, molding members are desired to efficiently dissipate heat generated when the semiconductor chips are driven.

### SUMMARY

The present disclosure relates to a resin composition for a molding member having an improved heat dissipation characteristic and a semiconductor package using the resin composition.

In some implementations, a resin composition for forming a molding member included in a semiconductor package includes about 2 weight percent (wt %) to about 10 wt % of epoxy resin, about 2 wt % to about 10 wt % of a hardener, about 50 wt % to about 90 wt % of a filler, about 5 wt % to about 20 wt % of a phase-change material composite particle, and about 0 wt % to about 5 wt % of an additive, wherein the phase-change material composite particle includes a core particle including a phase-change material and a shell layer surrounding a surface of the core particle and including an organic material or an inorganic material.

In some implementations, a semiconductor package includes a semiconductor chip and a molding member arranged on at least one of top, side, and bottom surfaces of the semiconductor chip, wherein the molding member includes a polymer matrix, a filler dispersed in the polymer matrix and including at least one selected from silica, alumina, magnesium oxide, aluminum nitride, and boron nitride, and phase-change material composite particles disposed in the polymer matrix, wherein each of the phase-change material composite particles includes a core particle including a phase-change material and a shell layer surrounding a surface of the core particle and including an organic material or an inorganic material.

In some implementations, a semiconductor package includes a substrate, a semiconductor chip mounted on the substrate, and a molding member on the substrate and surrounding a top surface and a side surface of the semiconductor chip, wherein the molding member includes a polymer matrix based on epoxy resin, a filler dispersed in the polymer matrix, and phase-change material composite particles dispersed in the polymer matrix, wherein each of the phase-change material composite particles includes a core particle including a phase-change material and a shell layer surrounding a surface of the core particle, the core particle includes at least one selected from paraffin, glycol, a fatty acid, an ester, and derivatives thereof, the shell layer includes at least one selected from polyethylene, polypropylene, polyamide, polycarbonate, polyurethane, polysiloxane, polyacrylate, polyester, polyimide, and derivatives thereof or includes at least one selected from alumina, magnesium oxide, aluminum nitride, and boron nitride, and the filler includes at least one selected from silica, alumina, magnesium oxide, aluminum nitride, and boron nitride.

### BRIEF DESCRIPTION OF THE DRAWINGS

Implementations will be more clearly understood from the following detailed description taken in conjunction with the accompanying drawings.

FIG. 1 is a cross-sectional view of an example of a semiconductor package.

FIG. 2 is an example enlarged view of a region A in FIG. 1.

FIG. 3 is a schematic diagram showing an example of a heat dissipation path through phase-change material composite particles included in a molding member of a semiconductor package.

FIG. 4 is a schematic graph showing an example of a relationship between temperature and thermal energy of a molding member including phase-change material composite particles.

FIG. 5 is a flowchart of an example of a method of manufacturing a semiconductor package.

### DETAILED DESCRIPTION

Hereinafter, implementations will be described in detail with reference to the accompanying drawings.

Embodiments relate to a resin composition for a molding member included in a semiconductor package. In some implementations, a resin composition may be used in a method of manufacturing a semiconductor package, and a cured product of the resin composition may include a molding member included in the semiconductor package.

In some implementations, a resin composition may include epoxy resin, a hardener, a filler, a phase-change material composite particle, and an additive.

Table 1 shows the contents of epoxy resin, a hardener, a filler, a phase-change material composite particle, and an additive in a resin composition in units of wt %.

TABLE 1

| Substances | Content (wt %) |
|---|---|
| Epoxy resin | 2~10 |
| Hardener | 2~10 |
| Filler | 50~90 |
| Phase-change material | 5~20 |
| composite particles | |
| Additive | 0~5 |

In some implementations, about 2 wt % to about 10 wt % epoxy resin may be included in the resin composition. In some implementations, about 2 wt % to about 10 wt % hardener may be included in the resin composition. In some implementations, about 50 wt % to about 90 wt % filler may be included in the resin composition. In some implementations, about 5 wt % to about 20 wt % phase-change material composite particles may be included in the resin composition. In some implementations, about 0 wt % to about 5 wt % additive may be included in the resin composition.

In some implementations, the epoxy resin may correspond to a matrix or binder of a molding member that is formed by curing the resin composition. In some implementations, the epoxy resin may include at least one selected from bisphenol A epoxy, bisphenol F epoxy, rubber modified epoxy, novolac epoxy, cycloaliphatic epoxy, tetra-functional epoxy, acryl modified epoxy, coal tar modified epoxy, aliphatic chain modified epoxy, cresol novolac epoxy, polyglycol epoxy, cardanol epoxy, brominated epoxy, and phenoxy epoxy.

In some implementations, the hardener may react with epoxy resin in the resin composition and cause the curing reaction of the epoxy resin. In some implementations, the hardener may include at least one selected from an acid anhydride hardener, a cationic hardener, an imidazole hardener, a dicyandiamide hardener, and an amine adduct-type hardener.

In some implementations, the acid anhydride hardener may include at least one selected from dodecenyl succinic anhydride (DDSA), polyadipic acid (PADA), polysebacic acid (PSPA), methyl tetrahydrophthalic anhydride (Me-THPA), methyl hexahydrophthalic anhydride (Me-HHPA), methylhymic anhydride (MHAC), tetrahydrophthalic anhydride (THPA), phthalic anhydride (PA), trimethylicanhydride (TMA), pyromethylic anhydride (PMDA), benzophenon tetracarboxylic anhydride (BTDA), chlorendicanhydride (HET), and tetrabromo phthalic anhydride (TBPA).

In some implementations, the cationic hardener may include at least one selected from [4-acetyloxy)phenyl]dimthylsulfonium(OC-6-11)-hexafluoroantimonate(1-), PC-2508, CXC-1742, CXC-1751, N-benzylpyrazinium hexafluoroantimonate (BPH), XNA-2201, and XNA-2202.

In some implementations, the imidazole hardener may include at least one selected from 2-methylimidazole, 2-undecylimidazole, 2-heptadecylimidazole, 1,2-dimethylimidazole, 2-ethyl-4-methylimidazole, 2-phenylimidazole, 2-phenyl-4-methylimidazole, 1-benzyl-2-methylimidazole, 1-benzyl-2-phenylimidazole, 1-cyanoethyl-2-methylimidazole, 1-cyanoethyl-2-undecylimidazole, 1-cyanoethyl-2-ethyl-4-methylimidazole, 1-cyanoethyl-2-phenylimidazole, 1-cyanoethyl-2-undecylimidazolium trimellitate, 1-cyanoethyl-2-phenylimidazolium trimellitate, 2,4-diamino-6-[2′-methylimidazolyl-(1′)]-ethyl-s-triazine, 2,4-diamino-6-[2′-undecylimidazolyl-(1′)]-ethyl-s-triazine, 2,4-diamino-6-[2′-ethyl-4′-methylimidazolyl-(1′)]-ethyl-s-triazine, 2,4-diamino-6-[2′-methylimidazolyl-(1′)]-ethyl-s-triazineisocyanuric acid adduct, 2-phenylimidazoleisocyanuric acid adduct, 2-phenyl-4,5-dihydroxymethylimidazole, 2-phenyl-4-methyl-5-hydroxymethylimidazole, 2,3-dihydro-1H-pyrrolo[1,2-a]benzimidazole, 1-dodecyl-2-methyl-3-benzylimidazolium chloride, 2-methylimidazoline, and 2-phenylimidazoline.

In some implementations, the filler may be dispersed within the molding member to form a heat dissipation path and may reduce the coefficient of thermal expansion of the molding member and increase the thermal conductivity of the molding member. The filler may include an inorganic material having an excellent heat dissipation characteristic. In some implementations, the filler may include at least one selected from silica, alumina, magnesium oxide, aluminum nitride, and boron nitride.

In some implementations, the filler may be contained as particles or powder in the resin composition. After the resin composition is cured and converted into the molding member, the filler may be evenly dispersed in the molding member. Filler particles contained in the resin composition may be maintained in the molding member without volatilization or deformation.

In some implementations, the filler contained in the resin composition may have a particle size of about 0.1 micrometers to about 100 micrometers. In some implementations, the filler may have an average particle size of about 1 micrometer to about 50 micrometers.

In some implementations, a phase-change material composite particle may improve the heat dissipation characteristic of the molding member and may increase the toughness of the molding member. In some implementations, the phase-change material composite particle may include a core particle including a phase-change material and a shell layer on the surface of the core particle.

In some implementations, the core particle may include a material having a melting point within the operating temperature range of a semiconductor chip, e.g., a range of about 20° C. to about 100° C. In some implementations, the core particle may include a material having a melting point within a range of about 50° C. to about 100° C. In some implementations, the core particle may include a material absorbing heat when the temperature of the molding member is increased by heat generated from a semiconductor chip such that the phase of the core particle may change from a solid to a liquid. The core particle may include a material also discharging heat when the temperature of the molding member decreases such that the phase of the core particle may change from a liquid into a solid.

In some implementations, the core particle may include at least one organic material selected from paraffin, glycol, fatty acids, esters, and derivatives thereof. In some implementations, the core particle may include at least one selected from n-heptadecane, n-octadecane, n-nonadecane, n-eicosane, polyethylene glycol, a stearic acid, a palmitic acid, a lauric acid, and derivatives thereof.

In some implementations, the derivative of a palmitic acid that may be used as the core particle may include at least one selected from palmitic acid methyl ester, palmitic acid ethyl ester, palmitic acid propyl ester, palmitic acid vinyl ester, palmitic acid metal salt, palmitic alcohol, and palmitic amide. In some implementations, the derivative of a lauric acid that may be used as the core particle may include at least one selected from methyl ester, dodecyl ester, cetyl ester, phenacyl ester, and phenylhydrazide.

In some implementations, the core particle may have a particle size of about 1 micrometer to about 100 micrometers. In some implementations, the core particle may have a particle size of about 10 micrometers to about 50 micrometers.

In some implementations, a shell layer including an organic material or an inorganic material may be disposed on the surface of the core particle. In some implementations, the shell layer may completely cover the surface of the core particle. In some implementations, the shell layer may have a thickness of about 1 micrometer to about 10 micrometers.

In some implementations, because the shell layer surrounds the surface of the core particle, even when the phase of the core particle changes due to heat generated during the operation of a semiconductor chip, the phase-changed material of the core particle (e.g., a liquid core particle material or a gaseous core particle material) may be confined to a space limited by the shell layer, and the matrix of the molding member may not directly contact the phase-changed material of the core particle.

In some implementations, the shell layer may include an organic material. For example, the shell layer may include at least one selected from polyethylene, polypropylene, polyamide, polycarbonate, polyurethane, polysiloxane, polyacrylate, polyester, polyimide, and derivatives thereof. In some implementations, the shell layer may include an inorganic material. For example, the shell layer may include at least one selected from alumina, magnesium oxide, aluminum nitride, and boron nitride. In some implementations, the shell layer may have a relatively high thermal conductivity.

In some implementations, the shell layer may include a material that has not a boiling point or a melting point in the operating temperature range of a semiconductor chip, e.g., the range of about 0° C. to about 100° C. In other words, the shell layer may include a material that does not undergo phase change or maintains one state in the operating temperature range of a semiconductor chip, e.g., the range of about 0° C. to about 100° C. In some implementations, even when the phase of the core particle changes due to heat generated during the operation of a semiconductor chip, the shell layer may maintain its initial shape and phase without a phase change, and the phase-changed material of the core particle may be contained in the shell layer.

In some implementations, the phase-change material composite particle may be formed by using at least one selected from emulsion polymerization, phase separation, a sol-gel method, chemical vapor deposition, physical vapor deposition, and a crystal growth method.

In some implementations, the phase-change material composite particle may be formed by using emulsion polymerization. For example, a core particle including a phase-change material and a monomer of a shell layer may be added into a solvent. Under mechanical stirring, the monomer may be polymerized in the solvent so that the shell layer including an organic material may be conformally coated on the surface of the core particle. Thereafter, the solvent may be dried, and powder of the phase-change material composite particle may be obtained.

In some implementations, the phase-change material composite particle may be formed by using phase separation. For example, a first solution may be prepared by adding a polymer of a shell layer into a first solvent, and a colloidal solution may be prepared by dispersing core particles including a phase-change material in the first solution. Thereafter, the colloidal solution may be dropped and stirred into a second solvent having a physical property (e.g., the solubility of a polymer in a solvent or the polarity of a solvent) that is different from the physical property of the first solvent so that the shell layer may be conformally coated on the surface of the core particle. Thereafter, the solvent may be dried, and powder of the phase-change material composite particle may be obtained.

In some implementations, the additive may include a pigment, a dye, a leveling agent, a foam breaker, an adhesion promoter, a coupling agent, a softener, or the like. In some implementations, the additive may be used to control a reaction rate, improve stability, and adjust color. In some implementations, about 0 wt % to about 5 wt % additive may be included in the resin composition. In other words, the additive may be selectively included in the resin composition. In some implementations, an additive may not be included in the resin composition.

In some implementations, the filler in the resin composition may include a material having a relatively high thermal conductivity, and the resin composition may have a filler content of about 50 wt % to about 90 wt %, based on the total weight thereof. Filler particles may be connected to each other and may thus form a heat dissipation path in the molding member so that heat generated during the operation of a semiconductor chip may be radiated to the outside of a semiconductor package through the heat dissipation path formed by the filler particles.

When a filler content is lower than 50 wt %, filler particles may not be connected to each other in the molding member. Accordingly, the heat dissipation path may not be sufficiently formed, and the heat dissipation characteristic of a semiconductor package may not be satisfactory. When a filler content is higher than 90 wt %, the modulus of the molding member may increase. Accordingly, the molding member may not sufficiently protect a semiconductor chip from an external impact, and the reliability of a semiconductor package may decrease.

In some implementations, the phase-change material composite particle in the resin composition may include a material that undergoes phase change in the operating temperature range of a semiconductor chip, for example, a material of which the phase is changed from a solid to a liquid by heat generated during the operation of the semiconductor chip. The phase-change material composite particle may absorb heat during the phase change, thereby reducing and/or preventing an increase in temperature of the molding member.

The phase-change material composite particle may also include a core particle including an organic material or, in some implementations, may include a shell layer including an organic material. An organic material included in the phase-change material composite particle may have a lower modulus (or elastic modulus) than an inorganic material. The resin composition containing this phase-change material composite particle may have enhanced crack resistance.

In some implementations, the resin composition may have a phase-change material composite particle content of about 5 wt % to about 20 wt %, based on the total weight thereof. When a phase-change material composite particle content is lower than 5 wt %, the heat absorption effect of the molding member may be insignificant. When a phase-change material composite particle content is higher than 20 wt %, the toughness of the molding member may be decreased so that the reliability of a semiconductor package may also be decreased.

In the resin composition according to the implementations described above, the phase-change material composite particle may absorb heat generated during the operation of a semiconductor chip, and accordingly, a semiconductor package including the cured product of the resin composition as a molding member may have an excellent heat dissipation characteristic. Because the molding member has an enhanced toughness, damage to the semiconductor chip due to external stress and deformation may be prevented, and the reliability of the semiconductor package may be increased.

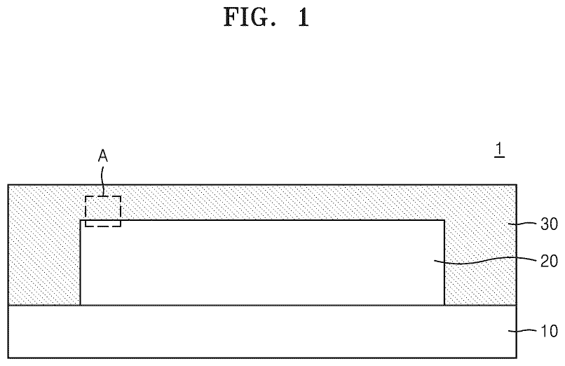

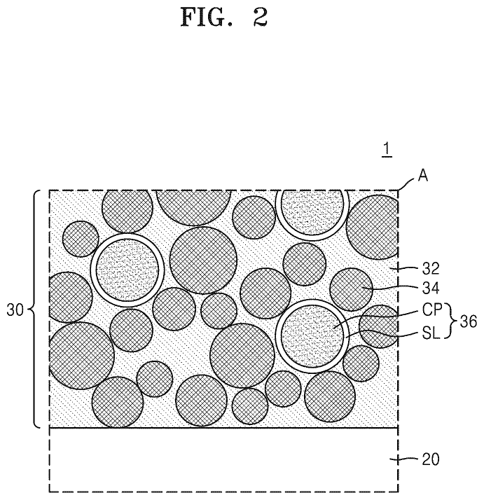

FIG. 1 is a cross-sectional view of an example of a semiconductor package 1. FIG. 2 is an example enlarged view of a region A in FIG. 1.

The semiconductor package 1 of FIGS. 1 and 2 may be formed using a resin composition produced.

Referring to FIGS. 1 and 2, the semiconductor package 1 may include a package substrate 10, a semiconductor chip 20, and a molding member 30. In some implementations, the molding member 30 may be arranged on the package substrate 10 to surround the top and side surfaces of the semiconductor chip 20. The molding member 30 may correspond to the cured product of a resin composition.

In some implementations, the package substrate 10 may include a printed circuit board or an interposer. In some implementations, the package substrate 10 may include a carrier substrate. In some implementations, instead of the package substrate 10, a redistribution structure including a stack structure of a redistribution insulating layer and a redistribution layer may be provided.

In some implementations, the semiconductor chip 20 may be mounted on the package substrate 10. The semiconductor chip 20 may include a logic chip, such as a central processing unit (CPU), a graphics processing unit (GPU), a field programmable gate array (FPGA), an application processor (AP), a digital signal processor, a cryptographic processor, a microprocessor, a microcontroller, an analog-to-digital converter, or an application-specific integrated circuit (ASIC), and/or a memory chip including volatile memory, such as dynamic random access memory (DRAM) or static RAM (SRAM), and non-volatile memory, such as phase-change RAM (PRAM), magnetic RAM (MRAM), resistive RAM (RRAM), or flash memory.

In some implementations, a plurality of semiconductor chips 20 may be mounted on the package substrate 10 in the horizontal direction and/or may be stacked on the package substrate 10 in the vertical direction.

In some implementations, the molding member 30 may include a matrix 32, a filler 34, and a phase-change material composite particle 36. The filler 34 and the phase-change material composite particle 36 may be dispersed in the matrix 32.

In some implementations, the matrix 32 may include an epoxy resin-based polymer matrix. In some implementations, the matrix 32 may be formed by curing the resin composition according to the implementations described above and may include epoxy resin and a polymer of a hardener. Optionally, when an additive is included in the resin composition, the additive may also be included in the matrix 32.

In some implementations, the filler 34 may include about 50 wt % to about 90 wt % inorganic material-based filler contained in the resin composition. As described above, the filler 34 may include at least one selected from silica, alumina, magnesium oxide, aluminum nitride, and boron nitride.

In some implementations, the filler 34 may have a particle size of about 0.1 micrometers to about 100 micrometers. In some implementations, the filler 34 may have an average particle size of about 1 micrometer to about 50 micrometers. In some implementations, content of the filler 34 may be about 50 wt % to about 90 wt %, based on the total weight of the molding member 30.

In some implementations, the phase-change material composite particle 36 may include a core particle CP and a shell layer SL. The core particle CP may include a phase-change material. The shell layer SL may be disposed on the surface of the core particle CP. In some implementations, the core particle CP may include a material that absorbs heat when the temperature of the molding member 30 is increased by heat generated from the semiconductor chip 20 so that the phase of the core particle CP may change from a solid to a liquid.

In some implementations, the core particle CP may include at least one organic material selected from paraffin, glycol, fatty acids, esters, and derivatives thereof. In some implementations, the core particle CP may include at least one selected from n-heptadecane, n-octadecane, n-nonadecane, n-eicosane, polyethylene glycol, a stearic acid, a palmitic acid, a lauric acid, and derivatives thereof.

In some implementations, the derivative of a palmitic acid that may be used as the core particle CP may include at least one selected from palmitic acid methyl ester, palmitic acid ethyl ester, palmitic acid propyl ester, palmitic acid vinyl ester, palmitic acid metal salt, palmitic alcohol, and palmitic amide. In some implementations, the derivative of a lauric acid that may be used as the core particle may include at least one selected from methyl ester, dodecyl ester, cetyl ester, phenacyl ester, and phenylhydrazide.

In some implementations, the core particle CP may have a particle size of about 1 micrometer to about 100 micrometers. In some implementations, the core particle CP may have a particle size of about 10 micrometers to about 50 micrometers.

In some implementations, the shell layer SL may include an organic material. For example, the shell layer SL may include at least one selected from polyethylene, polypropylene, polyamide, polycarbonate, polyurethane, polysiloxane, polyacrylate, polyester, polyimide, and derivatives thereof.

In some implementations, the shell layer SL may include an inorganic material. For example, the shell layer SL may include at least one selected from alumina, magnesium oxide, aluminum nitride, and boron nitride. In some implementations, the shell layer SL may have a relatively high thermal conductivity.

In some implementations, the shell layer SL may completely cover the surface of the core particle CP. In some implementations, the shell layer SL may have a thickness of about 1 micrometer to about 10 micrometers.

In some implementations, content of the phase-change material composite particle 36 may be about 5 wt % to about 20 wt %, based on the total weight of the molding member 30.

In the semiconductor package 1, the phase-change material composite particle 36 may absorb heat generated during the operation of the semiconductor chip 20. Accordingly, the semiconductor package 1 may have an excellent heat dissipation characteristic. Because the molding member 30 has an enhanced toughness, damage to the semiconductor chip 20 due to external stress and deformation may be prevented, and the reliability of the semiconductor package 1 may be increased.

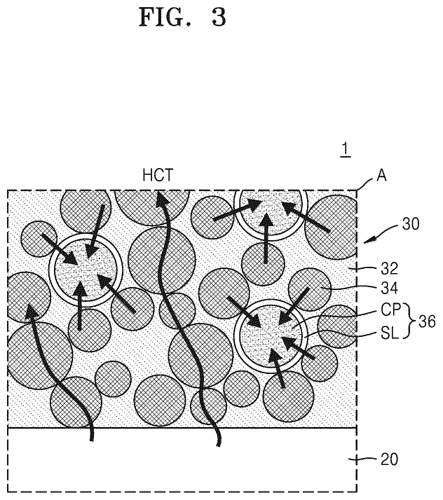

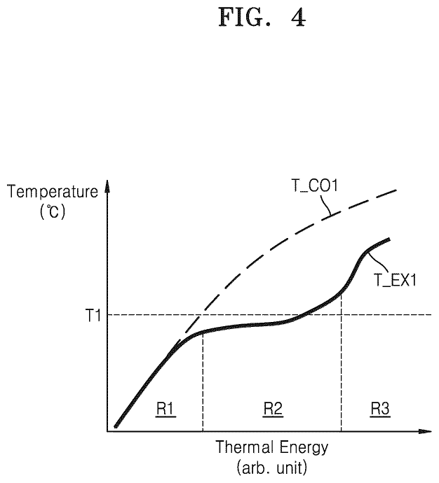

FIG. 3 is a schematic diagram showing an example of a heat dissipation path through phase-change material composite particles included in a molding member of a semiconductor package. FIG. 4 is a schematic graph showing an example of a relationship between temperature and thermal energy of a molding member including a phase-change material composite particle.

Referring to FIG. 3, the filler 34 and the phase-change material composite particle 36 may be dispersed and connected to each other in the matrix 32. The filler 34 may include a material having a relatively high thermal conductivity. A heat conduction path HCT may be formed from the surface (e.g., the top or side surface) of the semiconductor chip 20, which is in contact with the molding member 30, through particles of the filler 34. For convenience of understanding, the thermal conduction path HCT formed by particles of the filler 34 is schematically shown by an arrow in FIG. 3.

Phase-change material composite particles 36 may be dispersed in the molding member 30 and may be connected to the filler 34. The shell layer SL may include a material having a relatively high thermal conductivity and may quickly receive heat from the filler 34 that is adjacent or connected to the shell layer SL. The core particle CP inside the shell layer SL may include a phase-change material, which may absorb heat transmitted to the core particle CP and undergo a phase-change. In other words, heat may be transmitted from the surroundings of the phase-change material composite particle 36 to the core particle CP and may be absorbed by the core particle CP.

FIG. 4 schematically shows a temperature curve T_EX1 of a molding member including a phase-change material composite particle. For comparison, a temperature curve T_CO1 of a molding member that does not include a phase-change material composite particle in a comparative example is also shown as a dashed line in FIG. 4.

Referring to FIG. 4, in the comparative example, the temperature of the molding member gradually increases as the amount of thermal energy increases.

Contrarily, in some implementations, as the amount of thermal energy increases, the temperature of the molding member may gradually increases in a first range R1, may stagnate at around a first temperature T1 in a second range R2, and may increase again in a third range R3.

Here, the first temperature T1 may correspond to the phase-change temperature of a phase-change material. For example, the first temperature T1 may correspond to the melting point of some phase-change materials.

For example, in the first range R1, a phase-change material may be maintained in a solid state, and the temperature of the phase-change material (or the temperature of the molding member including the phase-change material) may increase due to thermal energy provided from the outside. In the second range R2, the phase-change material may absorb thermal energy provided from the outside and may undergo phase change from a solid state into a liquid state, and the temperature of the molding member may not increase or may slightly increase during the phase change of the phase-change material. In the third range R3, the phase-change material may be maintained in the liquid state, and the temperature of the phase-change material may increase due to thermal energy provided from the outside.

As shown in FIG. 4, the molding member including a phase-change material composite particle may have a lower temperature than the molding member that does not include a phase-change material composite particle in the comparative example.

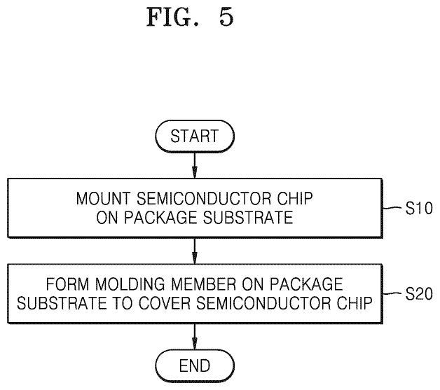

FIG. 5 is a flowchart of an example of a method of manufacturing a semiconductor package.

Referring to FIG. 5, the method of manufacturing a semiconductor package may include mounting a semiconductor chip on a package substrate in operation S10 and forming a molding member on the package substrate to cover the semiconductor chip in operation S20.

In some implementations, one or more semiconductor chips may be mounted on the package substrate in operation S10. For example, a plurality of semiconductor chips may be mounted on the package substrate in the horizontal direction, and/or a plurality of semiconductor chips may be stacked on the package substrate in the vertical direction. A semiconductor chip may be electrically connected to a connection terminal provided on or in the package substrate. For example, the semiconductor chip may be electrically connected to the connection terminal in a flip-chip manner or a wire bonding manner.

In some implementations, the package substrate may include an interposer or a printed circuit board. In some implementations, the semiconductor chip may be mounted on a carrier substrate instead of the package substrate. In some implementations, the semiconductor chip may be mounted on a redistribution structure instead of the package substrate.

In some implementations, the molding member may be formed using the resin composition produced in operation S20.

In some implementations, the molding member using the resin composition may be formed by transfer molding. The molding member may be formed by arranging the package substrate and the semiconductor chip in a cavity of a transfer mold, putting the resin composition into the transfer mold, and curing the resin composition. To put the resin composition into the cavity of the transfer mold, the resin composition may be formed as a tablet or a pellet.

In some implementations, the molding member using the resin composition may be formed by compress molding. Granules or powder of the resin composition may be put into a cavity of a mold die, and the resin composition may be changed into a gel state. Thereafter, the molding member may be formed by curing the resin composition in a state where the package substrate and the semiconductor chip are tightly put into the cavity of the mold die.

The semiconductor package may be completely manufactured by performing the processes described above.

In some implementations, a resin composition for a molding member may include a phase-change material composite particle, and the phase-change material composite particle may include a core particle including a phase-change material and a shell layer disposed on the surface of the core particle. The phase-change material composite particle may include a phase-change material that may undergo a phase change by absorbing heat generated during the operation of a semiconductor chip, and accordingly, a semiconductor package including the cured product of the resin composition as a molding member may have an excellent heat dissipation characteristic. Because the molding member has enhanced toughness due to a low modulus, damage to a semiconductor chip due to external stress and deformation may be prevented, and the reliability of the semiconductor package may be increased.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been shown and described with reference to implementations thereof, it will be understood that various changes in form and details may be made therein without departing from the spirit and scope of the following claims.

What is claimed is:

1. A resin composition for forming a molding member included in a semiconductor package, the resin composition comprising:
2 wt % to 10 wt % of epoxy resin;
2 wt % to 10 wt % of a hardener;
50 wt % to 90 wt % of a filler;
5 wt % to 20 wt % of a phase-change material composite particle; and
0 wt % to 5 wt % of an additive,
wherein the phase-change material composite particle includes:
a core particle including a phase-change material; and
a shell layer surrounding a surface of the core particle and including an organic material or an inorganic material.

2. The resin composition of claim 1, wherein the core particle includes at least one of paraffin, glycol, a fatty acid, an ester, derivatives of the paraffin, derivatives of the glycol, derivatives of the fatty acid, or derivatives of the ester.

3. The resin composition of claim 1, wherein the core particle includes at least one of n-heptadecane, n-octadecane, n-nonadecane, n-eicosane, polyethylene glycol, a stearic acid, a palmitic acid, a lauric acid, derivatives of the n-heptadecane, derivatives of the n-octadecane, derivatives of the n-nonadecane, derivatives of the n-eicosane, derivatives of the polyethylene glycol, derivatives of the stearic acid, derivatives of the palmitic acid, or derivatives of the lauric acid.

4. The resin composition of claim 1, wherein the shell layer includes at least one of polyethylene, polypropylene, polyamide, polycarbonate, polyurethane, polysiloxane, polyacrylate, polyester, polyimide, derivatives of the polyethylene, derivatives of the polypropylene, derivatives of the polyamide, derivatives of the polycarbonate, derivatives of the polyurethane, derivatives of the polysiloxane, derivatives of the polyacrylate, derivatives of the polyester, or derivatives of the polyimide.

5. The resin composition of claim 1, wherein the shell layer includes at least one of alumina, magnesium oxide, aluminum nitride, or boron nitride.

6. The resin composition of claim 1, wherein the phase-change material of the core particle has a melting point in a range of 20° C. to 100° C.

7. The resin composition of claim 1, wherein the core particle has a particle size of 1 micrometer to 100 micrometers.

8. The resin composition of claim 1, wherein the shell layer surrounds the surface of the core particle and has a thickness of 1 micrometer to 10 micrometers.

9. The resin composition of claim 1, wherein
the filler includes at least one of silica, alumina, magnesium oxide, aluminum nitride, or boron nitride, and
the filler has a particle size of 0.1 micrometers to 100 micrometers.

10. A semiconductor package comprising:
a semiconductor chip; and
a molding member on at least one of a top surface, a side surface, or a bottom surface of the semiconductor chip,
wherein the molding member includes:
a polymer matrix;
a filler dispersed in the polymer matrix and including at least one of silica, alumina, magnesium oxide, aluminum nitride, or boron nitride; and
a plurality of phase-change material composite particles disposed in the polymer matrix,
wherein each of the plurality of phase-change material composite particles includes:
a core particle including a phase-change material; and
a shell layer surrounding a surface of the core particle and including an organic material or an inorganic material.

11. The semiconductor package of claim 10, wherein the polymer matrix includes epoxy resin.

12. The semiconductor package of claim 10, wherein the core particle includes at least one of paraffin, glycol, a fatty acid, an ester, derivatives of the paraffin, derivatives of the glycol, derivatives of the fatty acid, or derivatives of the ester.

13. The semiconductor package of claim 10, wherein the core particle includes at least one of n-heptadecane, n-octadecane, n-nonadecane, n-eicosane, polyethylene glycol, a stearic acid, a palmitic acid, a lauric acid, derivatives of the n-heptadecane, derivatives of the n-octadecane, derivatives of the n-nonadecane, derivatives of the n-eicosane, derivatives of the polyethylene glycol, derivatives of the stearic acid, derivatives of the palmitic acid, or derivatives of the lauric acid.

14. The semiconductor package of claim 10, wherein the shell layer includes at least one of polyethylene, polypropylene, polyamide, polycarbonate, polyurethane, polysiloxane, polyacrylate, polyester, polyimide, derivatives of the polyethylene, derivatives of the polypropylene, derivatives of the polyamide, derivatives of the polycarbonate, derivatives of the polyurethane, derivatives of the polysiloxane, derivatives of the polyacrylate, derivatives of the polyester, or derivatives of the polyimide.

15. The semiconductor package of claim 10, wherein the shell layer includes at least one of alumina, magnesium oxide, aluminum nitride, or boron nitride.

16. The semiconductor package of claim 10, wherein the phase-change material of the core particle has a melting point in a range of 20° C. to 100° C.

17. The semiconductor package of claim 10, wherein the core particle has a particle size of 1 micrometer to 100 micrometers.

18. The semiconductor package of claim 10, wherein the shell layer surrounds the surface of the core particle and has a thickness of 1 micrometer to 10 micrometers.

19. The semiconductor package of claim 10, wherein the filler has a particle size of 0.1 micrometers to 100 micrometers.

20. A semiconductor package comprising:
a substrate;
a semiconductor chip on the substrate; and
a molding member on the substrate and surrounding a top surface and a side surface of the semiconductor chip,
wherein the molding member includes:
a polymer matrix based on epoxy resin;
a filler dispersed in the polymer matrix; and
a plurality of phase-change material composite particles dispersed in the polymer matrix,
wherein each of the plurality of phase-change material composite particles includes:
a core particle including a phase-change material, and
a shell layer surrounding a surface of the core particle,
wherein the core particle includes at least one of paraffin, glycol, a fatty acid, an ester, derivatives of the paraffin, derivatives of the glycol, derivatives of the fatty acid, or derivatives of the ester,
wherein the shell layer includes:
at least one of polyethylene, polypropylene, polyamide, polycarbonate, polyurethane, polysiloxane, polyacrylate, polyester, polyimide, derivatives of the polyethylene, derivatives of the polypropylene, derivatives of the polyamide, derivatives of the polycarbonate, derivatives of the polyurethane, derivatives of the polysiloxane, derivatives of the polyacrylate, derivatives of the polyester, or derivatives of the polyimide, or
at least one of alumina, magnesium oxide, aluminum nitride, or boron nitride, and
wherein the filler includes at least one of silica, alumina, magnesium oxide, aluminum nitride, or boron nitride.
